(19) United States
(12) Patent Application Publication
(10) Pub. No.: US 2016/0133614 A1
(43) Pub. Date: May 12, 2016

(54) SEMICONDUCTOR PACKAGE WITH INCORPORATED INDUCTANCE ELEMENT

(71) Applicant: QUALCOMM Incorporated, San Diego, CA (US)

(72) Inventors: Shiqun GU, San Diego, CA (US); Ratibor RADOJCIC, San Diego, CA (US); Mustafa BADAROGLU, Leuven (BE); Chunlei SHI, San Diego, CA (US); Yuancheng Christopher PAN, Saratoga, CA (US)

(21) Appl. No.: 14/536,363

(22) Filed: Nov. 7, 2014

(51) Int. Cl. H01L 25/16; H01L 23/522; H01L 23/498; H01L 21/683; H01L 21/56; H01L 21/768; H01L 21/48; H01L 25/065; H01L 25/00

(52) U.S. Cl. CPC H01L 25/16; H01L 25/0657; H01L 23/5227; H01L 23/49816; H01L 25/50; H01L 21/565; H01L 21/768; H01L 21/486; H01L 21/6835; H01L 2225/06548; H01L 2221/68359

(57) ABSTRACT

The present disclosure provides semiconductor packages and methods for fabricating semiconductor packages. The semiconductor package may comprise a semiconductor device mounted to a first substrate, a voltage regulator mounted to the first substrate and coupled to the semiconductor device, and an inductive element located on a perimeter of the semiconductor device and coupled to the voltage regulator, wherein the inductive element is formed by a plurality of interconnected conductive elements extending vertically from the first substrate.

### INTRODUCTION

Aspects of this disclosure relate generally to semiconductor packages, and more particularly to improving power transmission to integrated circuits within semiconductor packages.

A conventional semiconductor package includes a semiconductor device, for example, a processor integrated circuit (IC), memory IC, die, chip, or the like. The processor is coupled to a voltage regulator, for example, a voltage regulator IC. The voltage regulator ensures a constant voltage supply is provided to the processor. This is an important function, because the transistors in the processor have narrow voltage tolerances. Voltages outside of the acceptable range can damage the processor or cause erratic results.

The processor is mounted on a package substrate, and the package substrate is mounted on a printed circuit board (PCB). Conventionally, a semiconductor device is mounted on one portion of the PCB, and a voltage regulator is mounted on another. The voltage supplied by the voltage regulator travels through the PCB to the processor. However, a voltage drop is known to occur due to the distance between the voltage regulator and the processor, which has a negative impact on the performance of the processor. Moreover, the distance between the voltage regulator and the processor can result in slow response times. In the event that current transients are too fast for the voltage regulator to respond, decoupling capacitors are sometimes provided additional power to the processor. However, the decoupling capacitors can occupy a large area, which has a negative impact on overall size.

Attempts have been made to incorporate a voltage regulator into the semiconductor package containing the processor. However, voltage regulators include passive components such as inductors and capacitors that may also be embedded in the semiconductor package. Inductors and capacitors are large, which increases the overall size of the semiconductor package, and/or the manufacturing cost of the semiconductor package. Attempts to reduce the size of passive components typically results in passive components with a low quality factor.

The quality factor of a passive component is defined by the energy stored in a passive component versus energy dissipated in the passive component. A quality factor for passive components embedded in a die can be low because the passive components are manufactured thin to fit in the die. As the amount of conducting material shrinks, conductive or magnetic losses increase and degrade the quality factor.

### SUMMARY

In one aspect, the present disclosure provides a semiconductor package comprising a semiconductor device mounted to a first substrate, a voltage regulator mounted to the first substrate and coupled to the semiconductor device, and an inductive element located on a perimeter of the semiconductor device and coupled to the voltage regulator, wherein the inductive element is formed by a plurality of interconnected conductive elements extending vertically from the first substrate.

In another aspect, the present disclosure provides a method of fabricating a semiconductor package comprising forming a plurality of vertical conductive elements and positioning a semiconductor device, mounting a first substrate to at least the conductive elements and the semiconductor device such that the conductive elements and the semiconductor device are coupled to a voltage regulator, and forming an inductive element located on a perimeter of the semiconductor device, wherein forming the inductive element comprises interconnecting the conductive elements.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the invention, and in which:

FIG. 1 is a schematic diagram of an exemplary arrangement of components in a semiconductor package in accordance with an aspect of the disclosure.

FIG. 2 is a schematic diagram of an exemplary arrangement of components in a semiconductor package in accordance with another aspect of the disclosure.

FIG. 3 is a schematic diagram of an exemplary arrangement of components in a semiconductor package in accordance with another aspect of the disclosure.

FIG. 4 is a schematic diagram of an exemplary inductive element in the semiconductor package of FIG. 3.

FIG. 5A is a schematic diagram of an exemplary arrangement of components in a stage of an exemplary fabrication process in accordance with an aspect of the disclosure.

FIG. 5B is a schematic diagram of an exemplary arrangement of components in another stage of the exemplary fabrication process.

FIG. 5C is a schematic diagram of an exemplary arrangement of components in another stage of the exemplary fabrication process.

FIG. 5D is a schematic diagram of an exemplary arrangement of components in another stage of the exemplary fabrication process.

FIG. 5E is a schematic diagram of an exemplary arrangement of components in another stage of the exemplary fabrication process.

FIG. 5F is a schematic diagram of an exemplary arrangement of components in another stage of the exemplary fabrication process.

FIG. 5G is a schematic diagram of an exemplary arrangement of components in another stage of the exemplary fabrication process.

FIG. 5H is a schematic diagram of an exemplary arrangement of components in another stage of the exemplary fabrication process.

FIG. 6 is a schematic diagram of an exemplary arrangement of components in a semiconductor package in accordance with another aspect of the disclosure.

FIG. 7 is a schematic diagram of an exemplary arrangement of components in a semiconductor package in accordance with another aspect of the disclosure.

FIG. 8 is a flow diagram of a method for fabricating a semiconductor package in accordance with another aspect of the disclosure.

FIG. 9 is a block diagram showing an exemplary wireless communication system in which an aspect of the disclosure may be advantageously employed.

FIG. 10 is a block diagram illustrating a design workstation used for circuit, layout, and logic design of the disclosed semiconductor IC package.

### DETAILED DESCRIPTION

Aspects of the disclosure are disclosed in the following description and related drawings directed to specific aspects of the disclosure. Alternate aspects may be devised without departing from the scope of the invention. Additionally, well-known elements of the invention will not be described in detail or will be omitted so as not to obscure the relevant details of the invention.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the invention” does not require that all aspects of the invention include the discussed feature, advantage or mode of operation.

As used herein, the term “vertical” is generally defined with respect to a surface of a substrate or carrier upon which a semiconductor package is formed. The substrate or carrier will generally define a “horizontal” plane, and a vertical direction approximates a direction that is roughly orthogonal to the horizontal plane.

To address some of the deficiencies in conventional systems, there is a need for a voltage regulator that is incorporated into a semiconductor package without greatly increasing the size of the semiconductor package. Moreover, the passive components associated with the voltage regulators may also be placed in close proximity to the processor without consuming large amounts of area in the semiconductor package. And the passive components may be made small without negatively impacting their quality factor. The present disclosure presents various arrangements of passive components, particularly inductors, in a semiconductor package. The present disclosure also presents various methods for fabricating the inductors in a semiconductor package.

In particular, the inductors are fabricated and arranged such that portions of the inductors extend vertically from a package substrate to which the processor and voltage regulator are mounted. In some aspects, these vertical elements comprise conductive posts or cylinders. In some aspects, a paramagnetic fill is disposed within the inductor, thereby increasing the inductance of the inductors. In particular, the paramagnetic fill may be disposed between the vertical conductive elements. The processor and voltage regulator may be mounted to opposite sides of the substrate (in a face-to-face arrangement), or to the same side. The resulting semiconductor package may be part of a package-on-package arrangement.

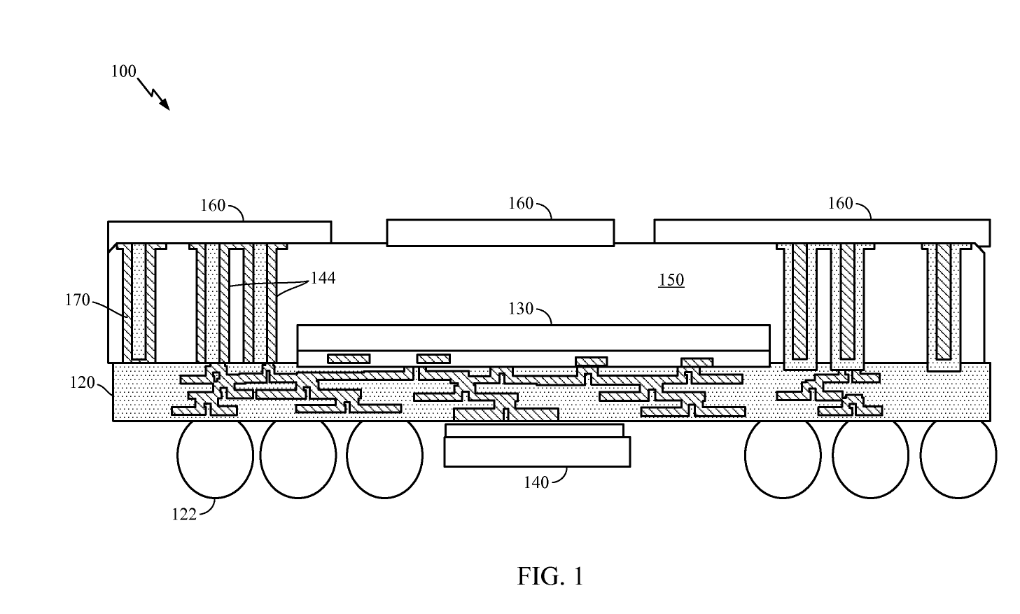

FIG. 1 generally illustrates a semiconductor package 100 according to an aspect of the invention. The semiconductor package 100 comprises a package substrate 120, denoted herein as a first substrate 120. A PCB (not shown) provides power to the first substrate 120 via one or more connections, such as, a ball of a ball grid array (BGA) 122.

In the illustrated arrangement, a semiconductor device 130 and a voltage regulator 140 are disposed on opposite sides of first substrate 120 in a face-to-face (F2F) arrangement. The semiconductor device 130 may be, for example, a processor IC, a memory IC, a die, a chip, a system on a chip (SoC), a mobile station modem™ (MSM™), or the like. The voltage regulator 140 may be, for example, a voltage regulator IC or a power management IC, or any other suitable power regulating device. Semiconductor device 130 and voltage regulator 140 may be disposed on the first substrate 120 using surface-mount technology (SMT). Semiconductor device 130 and voltage regulator 140 may be attached using an interconnect structure (not shown), for example, bumps, micro-bumps, pillars, and/or hybrid bonding. In one possible scenario, the power output of voltage regulator 140 is vertically aligned as closely as possible with a central processing unit (CPU) of semiconductor device 130. In another possible scenario, one or more of the first substrate 120, semiconductor device 130 and voltage regulator 140 comprises through vias which enable communication among the various elements of semiconductor package 100. Through vias may comprise through-silicon vias, through-substrate vias, through-mold vias, or any other vias the enable communication among the various elements of semiconductor package 100.

The first substrate 120 may contain at least one fan-out redistribution layer (RDL) which is used to distribute current. In one possible scenario, the PCB delivers power to at least one connection of BGA 122. The RDL distributes signals and/or power from the at least one connection of BGA 122 to the voltage regulator 140, from the voltage regulator 140 to at least one conductive element 144, and from the at least one conductive element 144 to the semiconductor device 130.

Conductive elements 144 (or posts) are disposed on a perimeter of the semiconductor device 130. The conductive elements 144 extend vertically upwards from the first substrate 120. In the illustrated arrangement, the conductive elements 144 comprise cylindrical elements which are constructed of a conductive material, for example, copper. However, the conductive elements 144 are not limited to a cylindrical shape and may take any the form of any given shape (e.g., rectangle, square, oval, etc.). The conductive elements 144 extend through a mold 150, which may be, for example, a molded underfill (MUF) or an epoxy mold compound (EMC). The conductive elements 144 may be embedded in the mold or inserted through vias, such as, for example, through-mold vias (TMV).

Second substrate 160 comprises, for example, conductive traces (not shown) which interconnect the respective second ends of a pair of conductive elements 144. First substrate 120 may also comprise conductive traces (not shown) which interconnect the respective first ends of a pair of conductive elements 144. An inductive element can be formed by the conductive elements 144, the conductive traces on the first substrate 120, and the conductive traces on the second substrate 160. In one possible scenario, a pair of interconnected conductive elements 144 forms a single coil of the inductive element. Optionally, other connections 170 are provided for transmitting signals through the mold 150. According to one possible aspect, the connections 170 are provided for transmitting signals from the semiconductor device 130 to a different semiconductor device (not shown) on the backside of a package-on-package dynamic random-access memory (DRAM).

FIG. 2 generally illustrates an semiconductor package 200 according to another aspect of the invention. Semiconductor package 200 is similar to semiconductor package 100 except that semiconductor package 200 is a bare-die arrangement in which the mold 150 is omitted. The remaining elements may be analogous to the similarly-numbered elements described with reference to FIG. 1.

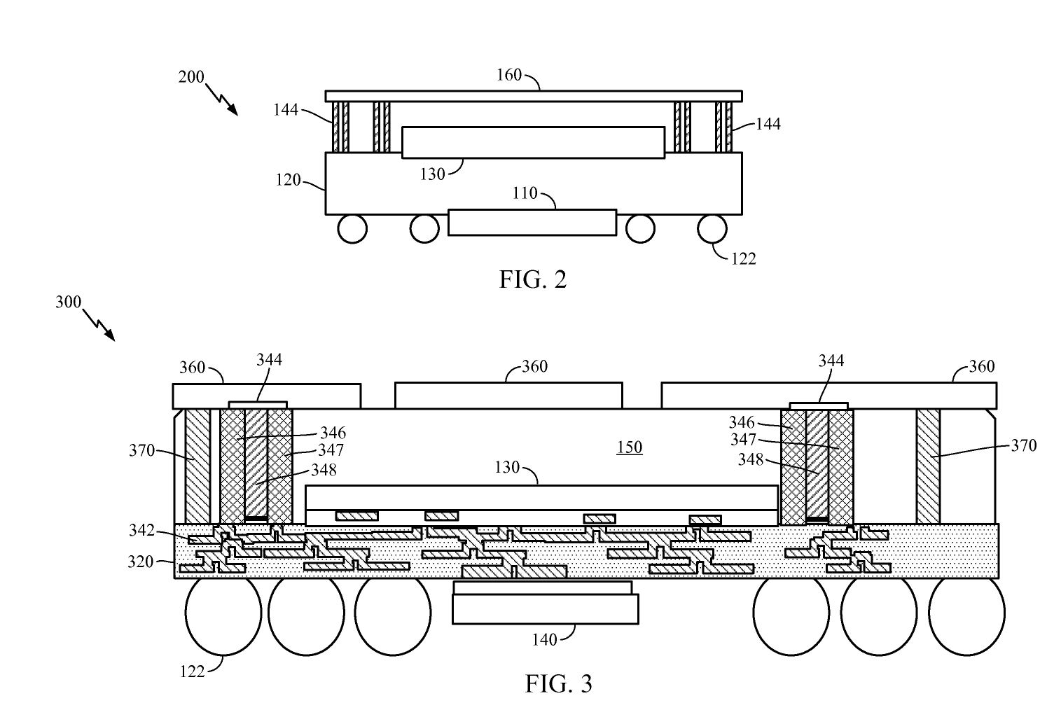

FIG. 3 generally illustrates an semiconductor package 300 according to another aspect of the invention. Semiconductor package 300, in contrast to semiconductor package 100, comprises fill 348. Alternatively, the fill 348 may comprise a paramagnetic fill, a ferromagnetic fill, or a non-conductive ferromagnetic fill. The fill 348 serves to increase the inductance of the adjacent inductive element. The fill 348 may be made of paramagnetic or ferromagnetic material, for example, one or more of ferrites, iron oxide, nickel oxide, iron particles within an insulator, nickel particles within an insulator, or any combination thereof. In one possible arrangement, fill 348 is disposed in at least a portion of an area lying between vertical conductive elements depicted in FIG. 3 as posts 346 and posts 347. Each of posts 346 and 347 may be made of conductive material, for example, copper. Although the vertical conductive elements 144 of FIG. 1 are shown as cylinders and the posts 346 and posts 347 of FIG. 3 are shown as posts, it will be understood that any of the vertical conductive elements provided in the present disclosure may selectively be formed as cylinders, posts, or any other shape suitable for conducting current. Other suitable shapes can include cylinders or posts with an octagonal cross-section or cylinders or posts with a vertical slope.

Semiconductor package 300 further comprises a first substrate 320 and a second substrate 360. First substrate 320 comprises one or more first traces 342 and second substrate 360 comprises one or more second traces 344. Each of traces 342 and 344 interconnects with one or more of post 346 and post 347. Traces 342 and 344 may be made of conductive material, for example, copper. Optionally, other connections 370 are provided for transmitting signals through mold 150. Although a mold 150 is shown in FIG. 3 similar to the mold 150 of FIG. 1, it will be understood that the mold 150 may be omitted as described with reference to FIG. 2. An inductive element can be formed by the posts 346, posts 347, first traces 342, and second traces 344. In one possible scenario, one of each of posts 346, posts 347, first traces 342, and second traces 344 are interconnected to form a single coil of the inductive element.

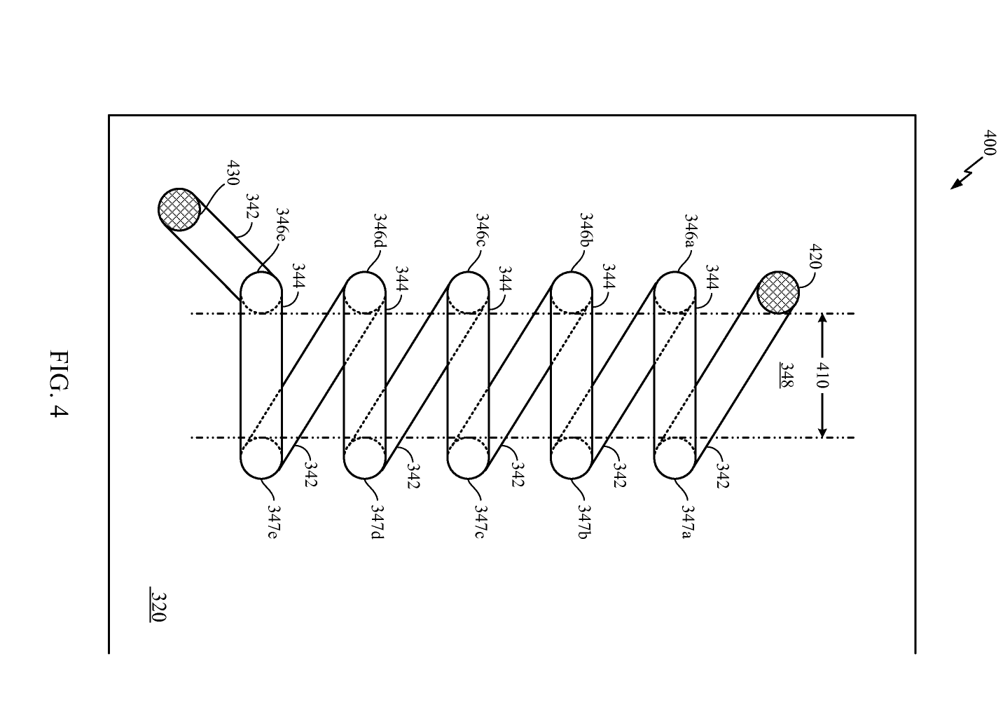

FIG. 4 generally illustrates an example of an inductive element 400. In the illustration of FIG. 4, inductive element 400 is shown disposed upon a portion of a substrate. The substrate may be, for example, first substrate 320 of semiconductor package 300 of FIG. 3, shown from a top-down view. Other elements from FIG. 3 are omitted in order to better illustrate inductive element 400. Inductive element 400 comprises an inductor input terminal 420 and an inductor output terminal 430. The inductor input terminal 420 and inductor output terminal 430 may interconnect with a fan-out redistribution layer (RDL) disposed in the first substrate 320.

In this example, the one or more posts 346 of FIG. 3 comprise posts 346a, 346b, 346c, 346d, and 346e, each of which are used to form the inductive element 400. In addition, the one or more posts 347 of FIG. 3 comprise posts 347a, 347b, 347c, 347d, and 347e, each of which are used to form the inductive element 400. Each of the five posts 346 is spaced from a corresponding post 347 by a cavity 410. The cavity 410 may be at least partially filled with fill 348. Second traces 344 interconnect the second ends of each of the posts 347 and 346. In particular, second traces 344 connect the second end of post 347a to the second end of post 346a, the second end of 347b to the second end of 346b, and so on. Second traces 344, each of which are used to form the inductive element 400, may be disposed on a second substrate (not shown), for example, second substrate 360 as described above.

First traces 342 connect the inductor input terminal 420 to the first end of post 347a. First traces 342 further interconnect the first ends of each of the posts 346 and 347. In particular, first traces 342 connect the inductor input terminal 420 to the first end of post 347a, the first end of post 346a to the first end of post 347b, the first end of 346b to the first end of 347c, and so on. First traces 342, each of which are used to form the inductive element 400, may be disposed on the first substrate 320.

In the arrangement of FIG. 4, current may enter inductor input terminal 420, whereupon it is conducted via first trace 342 to the first end of post 347a. After traveling to the second end of post 347a, the current is conducted via second traces 344 to the second end of post 346a. After traveling to the first end of post 346a, the current is conducted via first traces 342 to post 347b, and so on through each post, until it reaches post 346e. After traveling to the first end of post 346e, the current is conducted via first traces 342 to an inductor output terminal 430 which is disposed on the first substrate 320.

In the arrangement of FIG. 4, inductor input terminal 420 and inductor output terminal 430 are disposed separately from the first end of post 347a and the first end of post 346e, respectively, and connected to the first end of post 347a and the first end of post 346e, respectively, via first traces 342. However, it will be understood that the inductor input terminal 420 and inductor output terminal 430 need not be horizontally displaced with respect to the respective posts, and may in fact be built into the posts. Furthermore, it will be understood that inductor input terminal 420 and inductor output terminal 430 need not be disposed on first substrate 320. Either or both of inductor input terminal 420 and inductor output terminal 430 may be disposed on a second substrate such as, for example second substrate 360. In one possible scenario, one of inductor input terminal 420 and/or inductor output terminal 430 is interconnected to another inductor element, for example, a replication of inductive element 400. The interconnection may be provided by via second traces 344, first traces 342, first substrate 320, second substrate 360, any number of TSVs or TMVs, or any combination thereof.

Furthermore, it will be understood that none of posts 346 and 347, traces 342 and 344, cavity 410, inductor input terminal 420, or inductor output terminal 430 is drawn to scale. Moreover, the number of posts 346 or 347 need not equal five as it will be appreciated the number of posts, effective turns, fill material and the like can be adjusted to conform to the desired inductance and physical parameters of each implementation.

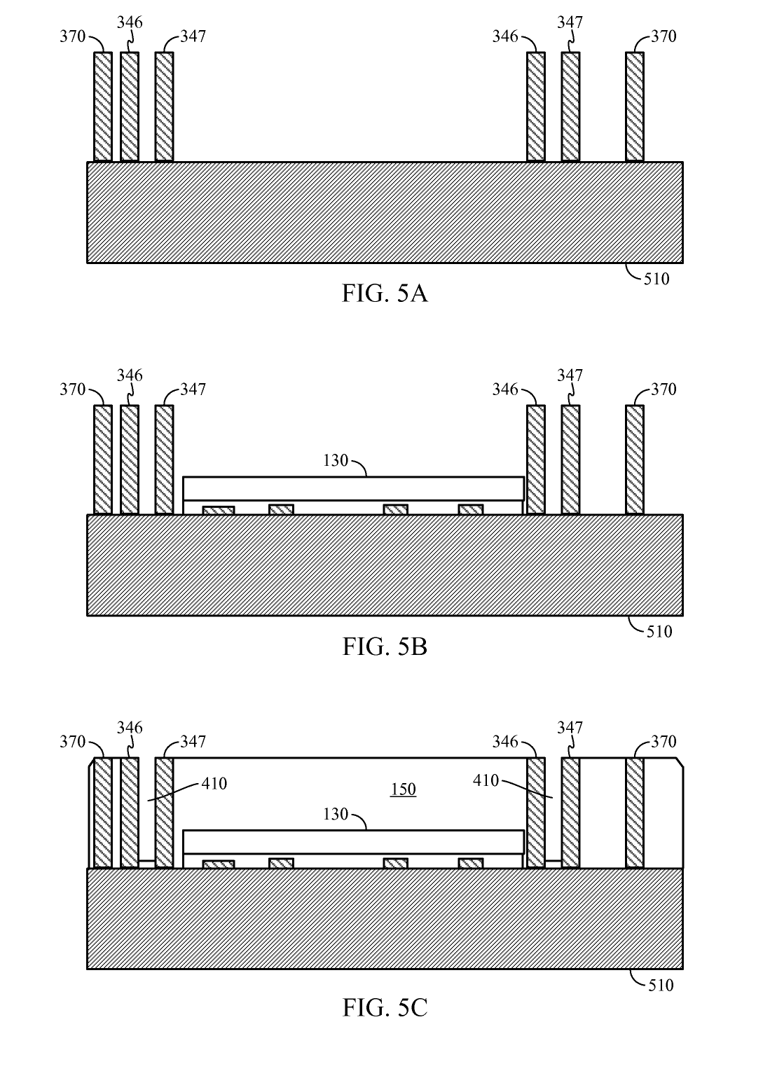

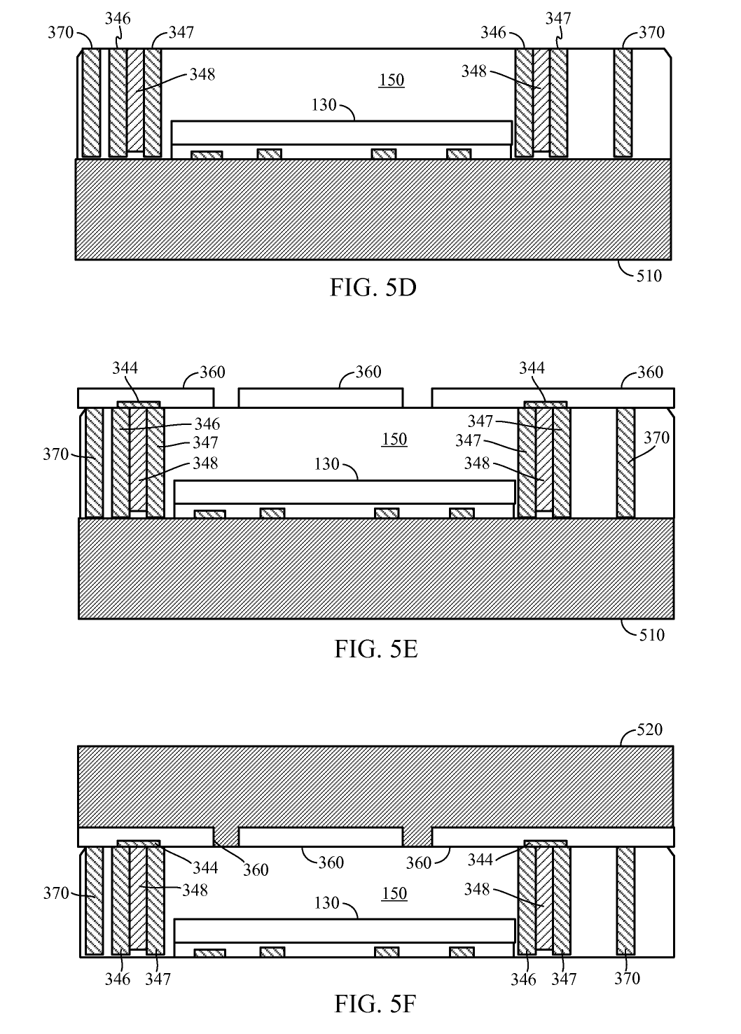

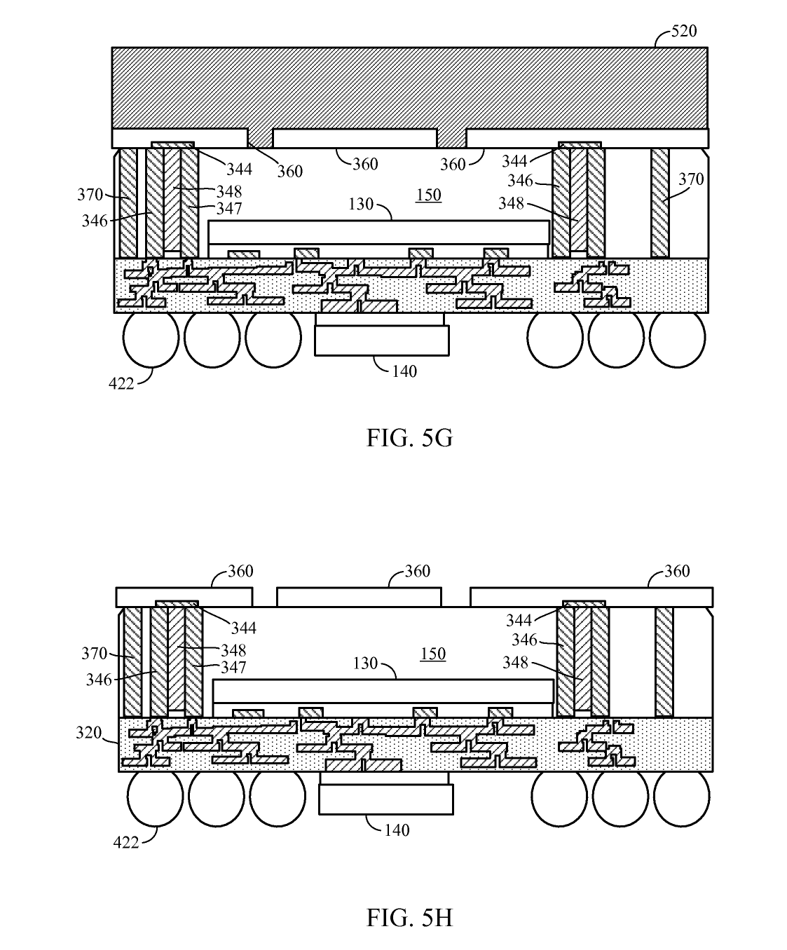

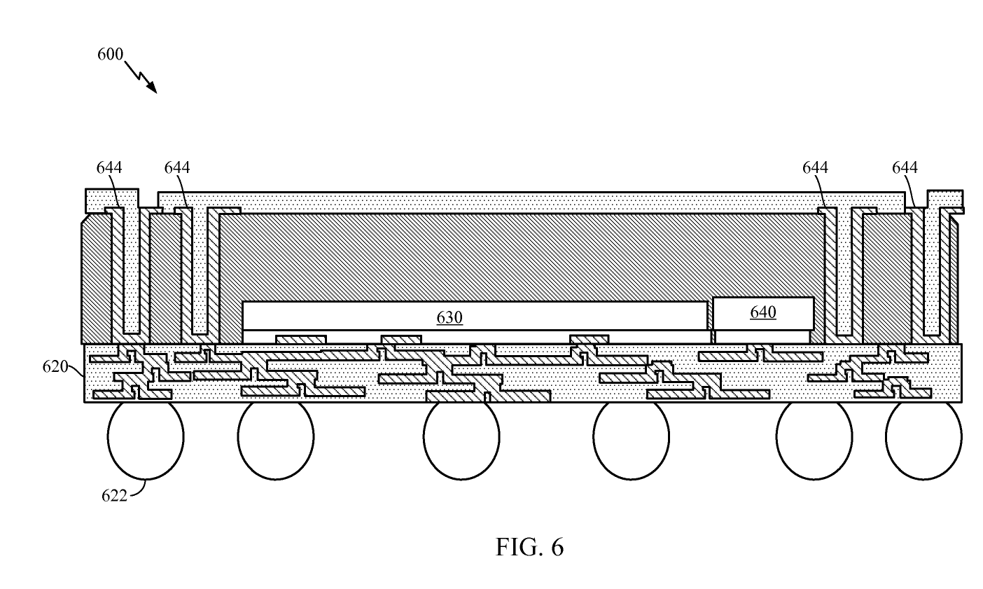

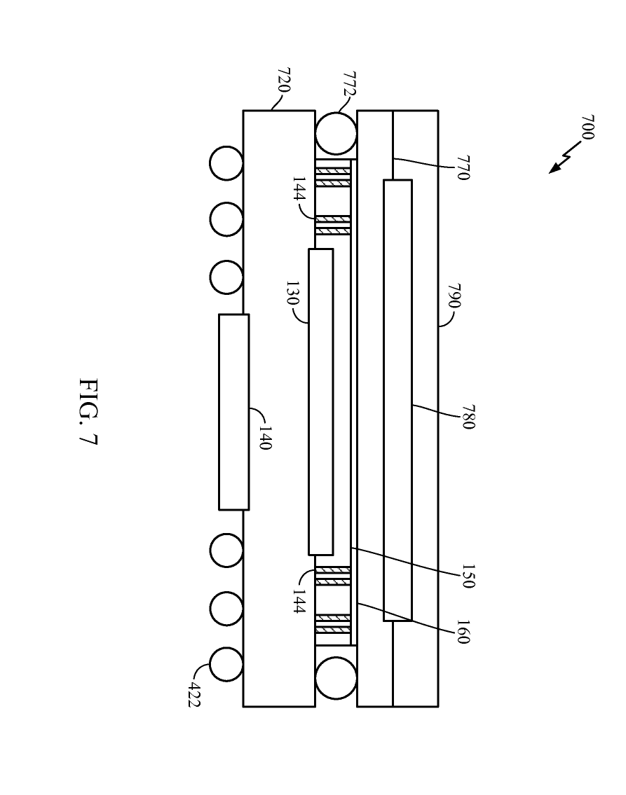

FIGS. 5A through 5H generally illustrate a process by which the arrangement of FIG. 3 and/or FIG. 4 can be provided. In FIG. 5A, posts 346 and 347 are shown formed on a carrier 510, in addition to optional connections 370. In FIG. 5B, semiconductor device 130 is shown placed face down on carrier 510. It will be understood that the posts 346 and 347, optional connections 370, and semiconductor device 130 may be placed on the carrier 510 in any suitable order. In FIG. 5C, the posts 346 and 347, optional connections 370, and semiconductor device 130 are embedded in a molding compound. The various elements shown are secured in a mold 150. After the applying the mold compound, an empty space or cavity is formed in the mold 150 between some conductive posts. The cavity may be formed by lithographic exposure and developing (using, e.g., a litho-patternable mold) or selective laser ablation. For example, cavity 410 is shown between posts 346 and 347.

In FIG. 5D, the cavity 410 is shown filled with fill 348. In FIG. 5E, traces such as, for example, second traces 344 are shown. The second traces 344 may be part of a redistribution layer that is embedded in second substrate 360. The second traces 344 for a portion of the loop for forming the inductor as illustrated in FIG. 4, for example. In FIG. 5F, the carrier 510 is de-mounted from the molded assembly and optionally a second carrier 520 is mounted to the molded assembly on the opposite side from carrier 510. In FIG. 5G, a first substrate having a fan-out redistribution layer such as, for example, first substrate 320, can be formed to provide connections between the posts 346 and 347, optional connections 370, and semiconductor device 130. In addition, a ball grid array and a voltage regulator such as, for example, ball grid array 422 can be formed and voltage regulator 440 can be mounted on the first substrate 320. Finally, in FIG. 5H, the optional carrier 520 is de-mounted/removed, leaving the completed semiconductor package with a processor integrated circuit (IC) 130 mounted on the first substrate 320, a voltage regulator 140 mounted on the first substrate 320 and coupled to the semiconductor device 130 and an inductive element, formed by a plurality of interconnected vertical conductive elements 346, 347, extending vertically from the first substrate 320, wherein the inductive element is located on a perimeter of the semiconductor device 130 and is coupled to the voltage regulator 140.

FIG. 6 generally illustrates a semiconductor package 600 according to another aspect of the invention. Semiconductor package 600 is similar to semiconductor package 100 except that semiconductor device 630 and voltage regulator 640 are not disposed on opposite sides of first substrate 620 in the face-to-face (F2F) arrangement. Instead, semiconductor device 630 and voltage regulator 640 are disposed on the same side of the first substrate 620. In some scenarios, semiconductor device 630 and voltage regulator 640 are analogous or identical to semiconductor device 130 and voltage regulator 140. Semiconductor device 630 and voltage regulator 640 may be disposed on the first substrate 620 using surface-mount technology (SMT). Semiconductor device 630 and voltage regulator 640 may be attached using an interconnect structure (not shown), for example, bumps, micro-bumps, pillars, and/or hybrid bonding. In one possible scenario, one or more of the first substrate 620, semiconductor device 630 and voltage regulator 640 comprises through vias which that enable communication among the various elements of semiconductor package 600. The vias may be similar to, for example, through vias 170 of FIG. 1.

The first substrate 620 may contain at least one fan-out redistribution layer (RDL) which can be used to distribute power and/or signals between the semiconductor device 630, voltage regulator 640 and inductive element formed by conductive elements 644. In one possible scenario, an external power source may deliver power to at least one ball 622 of the ball grid array (BGA). An RDL distributes current from the at least one ball of BGA 622 to the voltage regulator 640, from the voltage regulator 640 to at least one vertical conductive element 644, and from the at least one vertical conductive element 644 to the semiconductor device 630. The vertical conductive element 644 may be similar to the vertical conductive element 144 of FIG. 1 and/or posts 346, posts 347, and fill 348, shown in FIG. 3.

FIG. 7 generally illustrates a semiconductor package 700 according to another aspect of the invention. Semiconductor package 700 generally comprises a package-on-package (PoP) structure. Semiconductor package 700 may have a number of elements in common with semiconductor package 100, including semiconductor device 130, voltage regulator 140, conductive elements 144, mold 150, and second substrate 160. The semiconductor device 130 may be, for example, a processor chip or a processor integrated circuit. First substrate 720 is similar to first substrate 120 except that it is configured to connect to a top package substrate 770 via at least one connection 772. A semiconductor device 780 is mounted to top package substrate 770 in accordance with any mounting process set forth in this disclosure. The semiconductor device 780 may be, for example, a memory chip. The top package optionally comprises a mold 790 analogous or identical to mold 150, but may also be provided without mold 790 in a bare-die arrangement that is analogous to the arrangement of FIG. 2.

Although FIG. 7 shows a bottom package having mold 150 as set forth with reference to FIG. 1, it should be understood that an alternative arrangement, in which mold 150 is omitted as set forth with reference to FIG. 2, could also be adopted. Moreover, although FIG. 7 shows a bottom package having conductive elements 144 as set forth with reference to FIG. 1, it should be understood that an alternative arrangement, utilizing the posts 346, posts 347, and fill 348 of FIG. 3 could also be adopted. Moreover, although FIG. 7 shows a bottom package having an F2F arrangement of semiconductor device 130 and voltage regulator 140 as set forth with reference to FIG. 1, it should be understood that the same-side arrangement, utilizing the first substrate 620, semiconductor device 630 and voltage regulator 640 of FIG. 6, could also be adopted.

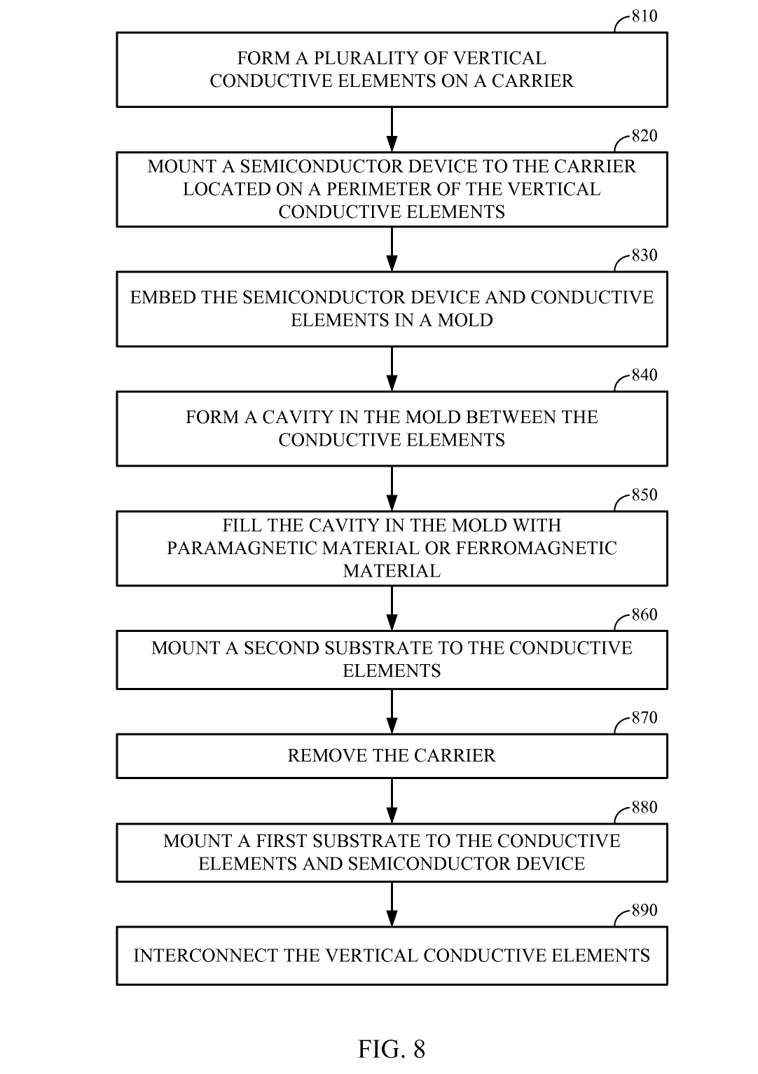

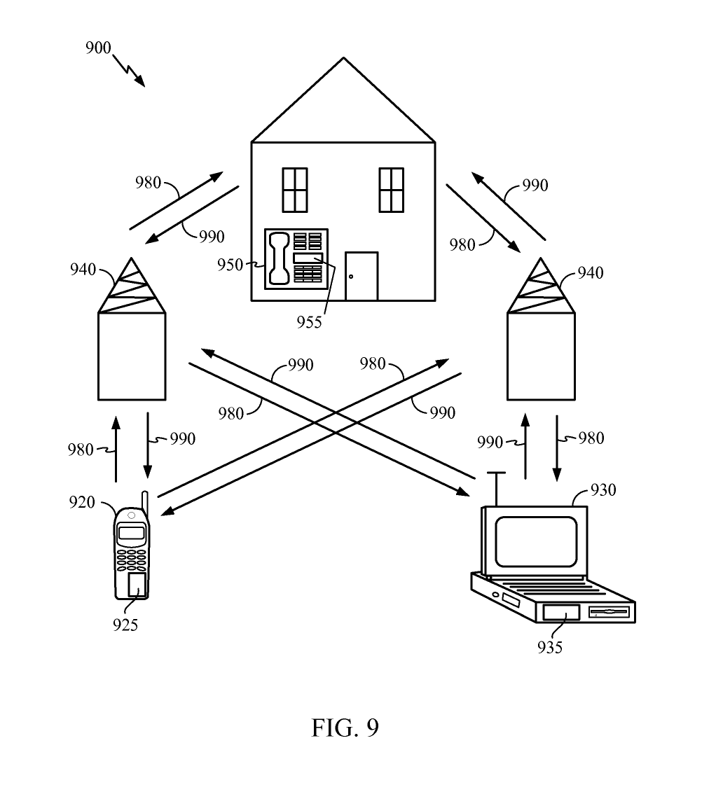

FIG. 8 generally illustrates an exemplary method 800 for fabricating a semiconductor package. The semiconductor package fabricated in method 800 may be similar to any of the semiconductor packages set forth in the present disclosure. At 810, a plurality of vertical conductive elements are formed on a carrier such that the vertical conductive elements extend vertically from the carrier. The vertical conductive elements may form a portion of an inductive element. At 820, a semiconductor device is mounted to the carrier. The semiconductor device may be mounted within a perimeter of the vertical conductive elements. Moreover, a voltage regulator may also be mounted to the carrier at 820 in order to form, for example, the semiconductor package of FIG. 6. It will be understood that the order of 810 and 820 may be reversed.

At 830, the semiconductor device and vertical conductive elements are embedded in a mold. Moreover, the voltage regulator may also be embedded in the mold in order to form, for example, the semiconductor package of FIG. 6. At 840, a cavity in the mold is formed by stripping the mold from between at least one pair of vertical conductive elements. The cavity may be formed by lithographic exposure and developing (using, e.g., a litho-patternable mold) or selective laser ablation. At 850, at least a portion of the cavity is at least partially filled with paramagnetic material or ferromagnetic material. At 860 a second substrate is mounted to the conductive elements. The second substrate comprises at least one second trace which interconnects respective second ends of the conductive elements.

At 870, the carrier is removed. At 880, a first substrate is mounted to the vertical conductive elements and the semiconductor device. The first substrate may comprise a power redistribution layer configured to couple a ball grid array to the voltage regulator and the voltage regulator to the inductive element and the semiconductor device. The first substrate comprises at least one first trace which interconnects respective first ends of the conductive elements. At 890, the vertical conductive elements are interconnected and an inductive element is formed. It will be understood that the interconnections may comprise the at least one first trace disposed on the first substrate and the at least one second trace disposed on the second substrate. One first trace and one second trace may interconnect at least one pair of vertical conductive elements to form a single turn in an inductive element.

FIG. 9 is a block diagram showing an exemplary wireless communication system 900 in which an aspect of the disclosure may be advantageously employed. For purposes of illustration, FIG. 9 shows three remote units 920, 930, and 950 and two base stations 940. It will be recognized that wireless communication systems may have many more remote units and base stations. Remote units 920, 930, and 950 include IC devices 925, 935 and 955, as disclosed below. It will be recognized that any device containing an IC may also include semiconductor components having the disclosed features and/or components manufactured by the processes disclosed here, including the base stations, switching devices, and network equipment. FIG. 9 shows forward link signals 980 from the base station 940 to the remote units 920, 930, and 950 and reverse link signals 990 from the remote units 920, 930, and 950 to base stations 940.

In FIG. 9, the remote unit 920 is shown as a mobile telephone, the remote unit 930 is shown as a portable computer, and the remote unit 950 is shown as a fixed location remote unit in a wireless local loop system. For example, the remote units may be a device such as a music player, a video player, an entertainment unit, a navigation device, a communications device, a personal digital assistant (PDA), a fixed location data unit, and a computer. Although FIG. 9 illustrates remote units according to the teachings of the disclosure, the disclosure is not limited to these exemplary illustrated units. The disclosure may be suitably employed in any device which includes semiconductor components, as described below.

The semiconductor packages disclosed herein (e.g., semiconductor package 300, semiconductor package 600, etc.) may be included in a device such as a set top box, a music player, a video player, an entertainment unit, a navigation device, a communications device, a personal digital assistant (PDA), a fixed location data unit, or a computer.

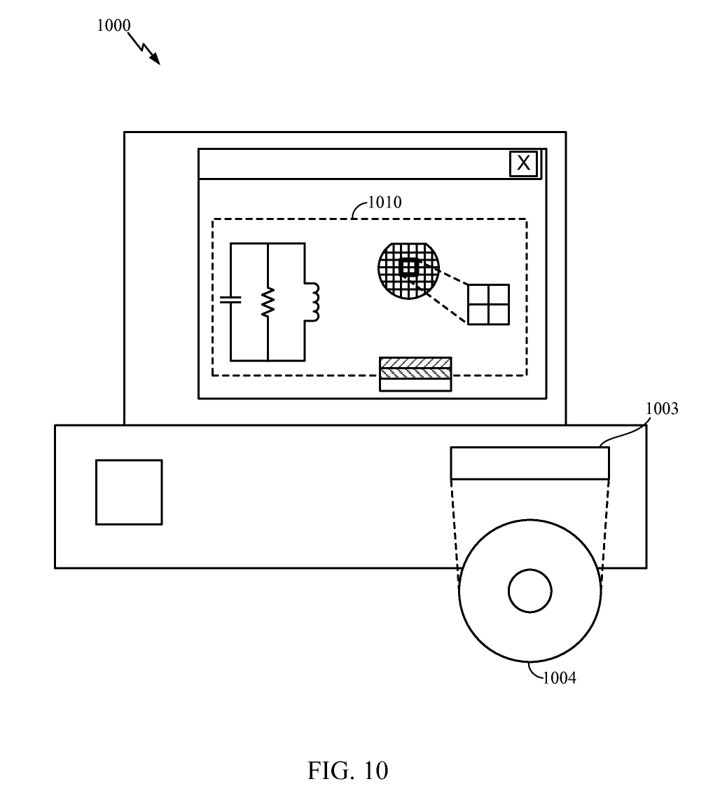

FIG. 10 is a block diagram illustrating a design workstation for circuit, layout, and design of a semiconductor part as disclosed herein. A design workstation 1000 may include a hard disk 1001 containing operating system software, support files, and design software such as Cadence or OrCAD. The design workstation 1000 also includes a display to facilitate design of a semiconductor part 1010 that may include a circuit and semiconductor dies. A storage medium 1004 is provided for tangibly storing the semiconductor part 1010. The semiconductor part 1010 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. Providing data on the storage medium 1004 facilitates the design of the semiconductor part 1010 by decreasing the number of processes for designing circuits and semiconductor dies.

The foregoing description may have references to discrete elements or properties, such as a capacitor, capacitive, a resistor, resistive, an inductor, inductive, conductor, conductive and the like. However, it will be appreciated that the various aspects disclosed herein are not limited to specific elements and that various components, elements or portions of components or elements may be used to achieve the functionality of one or more or discrete elements or properties. For example, a capacitive component or capacitive element may be a discrete device or may be formed by a specific arrangement of conductive traces separated by a dielectric material or combinations of thereof. Likewise, an inductive component or inductive element may be a discrete device or may be formed by a specific arrangement of conductive traces and materials (e.g., air core, magnetic, paramagnetic, etc.) or combinations of thereof. Similarly, a resistive component or resistive element may be a discrete device or may be formed by a semiconductor material, insulating material, adjusting the length and/or cross-sectional area of conductive traces, or combinations of thereof. Moreover, a specific arrangement of conductive traces and materials may provide one or more resistive, capacitive or inductive functions. Accordingly, it will be appreciated that the various components or elements disclosed herein are not limited to the specific aspects and or arrangements detailed, which are provided merely as illustrative examples.

While the foregoing disclosure shows illustrative aspects of the disclosure, it should be noted that various changes and modifications could be made herein without departing from the scope of the invention as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A semiconductor package comprising:
a semiconductor device coupled to a first substrate;
a voltage regulator coupled to the first substrate and coupled to the semiconductor device; and
an inductive element on a perimeter of the semiconductor device and coupled to the voltage regulator, wherein the inductive element is formed by a plurality of interconnected conductive elements extending vertically from the first substrate.

2. The semiconductor package of claim 1, wherein the inductive element comprises a paramagnetic material or ferromagnetic material disposed between at least two of the conductive elements.

3. The semiconductor package of claim 1, wherein the voltage regulator is coupled to a side of the first substrate which is opposite the side to which the semiconductor device is coupled.

4. The semiconductor package of claim 1, wherein the voltage regulator is coupled to the same side of the first substrate to which the semiconductor device is coupled and within a perimeter of the inductive element.

5. The semiconductor package of claim 1, wherein the first substrate comprises a power redistribution layer to couple a ball grid array to the voltage regulator, and the voltage regulator to the inductive element and the semiconductor device.

6. The semiconductor package of claim 1, wherein the inductive element comprises a plurality of inductive elements located on multiple sides of the perimeter of the semiconductor device.

7. The semiconductor package of claim 1, wherein the semiconductor package is coupled to a top package such that the semiconductor package forms a bottom package in a package-on-package structure.

8. The semiconductor package of claim 1, wherein:
each of the conductive elements comprises a first end and a second end;
the first end of at least one of the conductive elements is coupled via a first trace to the first end of another of the conductive elements; and
the second end of at least one of the conductive elements is coupled via a second trace to the second end of another of the conductive elements.

9. The semiconductor package of claim 8, wherein the first trace is disposed on the first substrate, and the conductive elements extend vertically from the first substrate in the same direction the semiconductor device the first substrate extends from the first substrate.

10. The semiconductor package of claim 8, wherein at least two of the conductive elements are separated by a cavity and the cavity is filled with a paramagnetic material or ferromagnetic material.

11. A device selected from the group consisting of a set top box, a music player, a video player, an entertainment unit, a navigation device, a communications device, a personal digital assistant (PDA), a fixed location data unit, and a computer, including the semiconductor package of claim 1.

12. A method of fabricating a semiconductor package, comprising:
forming a plurality of vertical conductive elements and positioning a semiconductor device;
coupling a first substrate to at least the conductive elements and the semiconductor device wherein coupling the first substrate comprises coupling the conductive elements and the semiconductor device to a voltage regulator; and
coupling an inductive element located on a perimeter of the semiconductor device, wherein forming the inductive element comprises interconnecting the conductive elements.

13. The method of fabricating the semiconductor package of claim 12, wherein forming the inductive element further comprises:
embedding at least the semiconductor device and the conductive elements in a mold;
removing at least a portion of the mold such that a cavity is formed between at least two of the conductive elements; and
filling at least a portion of the cavity with a paramagnetic material or a ferromagnetic material.

14. The method of fabricating the semiconductor package of claim 12, further comprising mounting the voltage regulator to the first substrate on a side of the first substrate which is opposite the side to which the semiconductor device is mounted or is to be mounted.

15. The method of fabricating the semiconductor package of claim 12, further comprising:
positioning the voltage regulator such that the inductive element is located on a perimeter of the voltage regulator,
wherein mounting the first substrate to at least the conductive elements and the semiconductor device further comprises mounting the first substrate to the voltage regulator such that the voltage regulator is mounted to the same side of the first substrate to which the semiconductor device is mounted.

16. The method of fabricating the semiconductor package of claim 12, wherein forming the inductive element further comprises forming a plurality of inductive elements located on multiple sides of the perimeter of the semiconductor device.

17. The method of fabricating the semiconductor package of claim 12, further comprising coupling a top package to the semiconductor package such that the semiconductor package forms a bottom package in a package-on-package structure.

18. The method of fabricating the semiconductor package of claim 12, wherein interconnecting the conductive elements comprises mounting a second substrate such that at least one second trace formed on the second substrate couples respective second ends of at least two of the conductive elements.

19. The method of fabricating the semiconductor package of claim 18, wherein interconnecting the conductive elements further comprises disposing the first substrate such that at least one first trace formed on the first substrate couples respective first ends of at least two of the conductive elements.

20. The method of fabricating the semiconductor package of claim 12, wherein:
forming the plurality of vertical conductive elements and positioning the semiconductor device further comprises forming the vertical conductive elements and positioning the semiconductor device on a carrier;
mounting the first substrate to at least the conductive elements and the semiconductor device further comprises removing the carrier.
